(19) United States
(12) Patent Application Publication
(10) Pub. No.: US 2020/0066615 A1
(43) Pub. Date: Feb. 27, 2020

(54) ELECTRONIC MODULE AND METHOD FOR THE PRODUCTION THEREOF

(71) Applicant: ZF Friedrichshafen AG, Friedrichshafen (DE)

(72) Inventors: Martin Hermann Hahn, Ebenweiler (DE); Thomas Preuschl, Sinzing (DE); Roland Friedl, Auerbach (DE)

(73) Assignee: ZF Friedrichshafen AG, Friedrichshafen (DE)

(21) Appl. No.: 16/461,176

(22) PCT Filed: Oct. 24, 2017
(86) PCT No.: PCT/EP2017/077097

§ 371 Date: May 15, 2019

(30) Foreign Application Priority Data
Nov. 15, 2016 (DE) 10 2016 222 376.3

(51) Int. Cl. H01L 23/473; H01L 23/367

(52) U.S. Cl. CPC H01L 23/473; H01L 23/367

(57) ABSTRACT

An electronics module may include at least one power semiconductor that is connected in a thermally conductive manner to an integral heat sink. The electronics module may further include a turbulence element that can move in a laser sintered cooling channel of the heat sink. The turbulence element may be laser sintered with the heat sink in a common laser sintering process.

### RELATED APPLICATIONS

This application is a filing under 35 U.S.C. § 371 of International Patent Application PCT/EP2017/077097, filed Oct. 24, 2017, and claiming priority to German Patent Application 10 2016 222 376.3, filed Nov. 15, 2016. All applications listed in this paragraph are hereby incorporated by reference in their entireties.

### TECHNICAL FIELD

The present invention relates to an electronics module and a method for the production of an electronics module.

### BACKGROUND

A heat transfer between a boundary surface and a liquid is delimited in a laminar flow by a slight vertical turbulence of the liquid. The heat transfer can be improved when the liquid exhibits a turbulence at the boundary surface.

US 2009/0183857 A1 describes a turbulator for a heat exchange tube.

Based on this, the present invention creates an improved electronics module and an improved method for the production of an electronics module according to the independent claims. Advantageous embodiments can be derived from the dependent claims and the following description.

### BRIEF SUMMARY

An electronics module is presented that has the following features:

at least one power semiconductor, which is connected in a thermally conductive manner to an integral laser sintered heat sink; and

a turbulence element that can move in a laser sintered cooling channel of the heat sink that is laser sintered with the heat sink in a process.

Power conductors are thermally sensitive, because the power losses when they are not cooled can lead to high temperatures that can irreversibly damage the semiconductor material of the power semiconductor. For this reason, the power semiconductor needs to be cooled as efficiently as possible. A good thermally conductive connection can be obtained, for example, through a thermally conductive adhesive. Laser sintering can be understood herein to mean additive manufacturing. Nearly any flow optimized and thermal resistance optimized heat sink can be produced through selective laser sintering. With laser sintering, individual particles of a powdered material are heated with a laser beam until the particles bond to one another at an atomic level. Components are constructed in layers in this manner. Sintering can take place at temperatures lower than the melting point of the material. The material can also be heated to the point where the particles begin to melt. The production process can be referred to as selective laser melting in this case. Modules with integrated hollow chambers can be produced through laser sintering. The unsintered powder in a hollow chamber is removed after the sintering process. The at least one cooling channel can be produced as such a hollow chamber. There can be a slight gap between the turbulence element and the heat sink. The gap can be produced by residual amounts of unsintered material.

The heat sink can be laser sintered from a metal material. The power semiconductor can be soldered to the heat sink. By reducing heat transfer resistances, a particularly good cooling effect can be obtained. For this, the power semiconductor can be soldered to a heat sink made of a material with a low thermal resistance. The material can be copper or aluminum.

The power semiconductor can be an IGBT. High capacities can be switched via an IGBT. The IGBT can be particularly heat sensitive.

A laser sintered shaft of the turbulence element can be rotatably supported in the cooling channel. Alternatively, the turbulence element can be rotatably supported on a laser sintered axle located in the cooling channel. Bearing points can be three dimensional.

The turbulence element can be perforated. The perforation generates additional turbulences in the coolant. The perforations are formed in the laser sintering.

The turbulence element can have an irregular shape. By way of example, a rotating turbulence element can be divided into non-uniform parts. Oscillations and/or resonances can be prevented due to the irregularity. Noises can thus be prevented by the irregular shape.

The turbulence element can be in the shape of a propeller. Alternatively, the turbulence element can be in the shape of a paddle. The coolant flow can cause a propeller to rotate. The propeller blades then generate turbulences in the coolant, which can convert a laminar flow to a turbulent flow. The coolant flow can cause a paddle-shaped turbulence element to oscillate, such that turbulences can likewise be generated in the coolant that can also convert the laminar flow to a turbulent flow.

The turbulence element can be laser sintered from a plastic material. The turbulence element can be made of a less thermally conductive material, because the turbulence element is not directly involved in the heat transfer.

The electronics module can have at least one further turbulence element that is laser sintered with the heat sink in a process and can move in the cooling channel. With numerous turbulence elements located successively in the coolant, the turbulence in the flow can be maintained over a longer distance.

Furthermore, a method for the production of an electronics module according to the approach presented herein is presented, wherein the method comprises the following steps:

providing a power semiconductor and an integral laser sintered heat sink with at least one cooling channel, in which a turbulence element is located that is laser sintered with the heat sink in a process; and

connecting the power semiconductor to the heat sink.

### BRIEF DESCRIPTION OF THE DRAWINGS

Exemplary embodiments of the approach presented herein are illustrated in the drawings, and explained in greater detail in the following description. Therein:

FIG. 1 shows an illustration of a conventional electronics module;

FIG. 2 shows an illustration of an electronics module with a pin-fin structure;

FIG. 3 shows an illustration of an electronics module according to an exemplary embodiment of the present invention;

FIG. 4 shows an illustration of a propeller-shaped turbulence element according to an exemplary embodiment of the present invention;

FIG. 5 shows an illustration of a paddle-shaped turbulence element according to an exemplary embodiment of the present invention; and

FIG. 6 shows a flow chart for a method for the production of an electronics module according to an exemplary embodiment of the present invention.

### DETAILED DESCRIPTION

In the following description of preferred exemplary embodiments of the present invention, identical or similar reference symbols are used for the elements shown in the various figures and having similar functions, wherein the descriptions of these elements shall not be repeated.

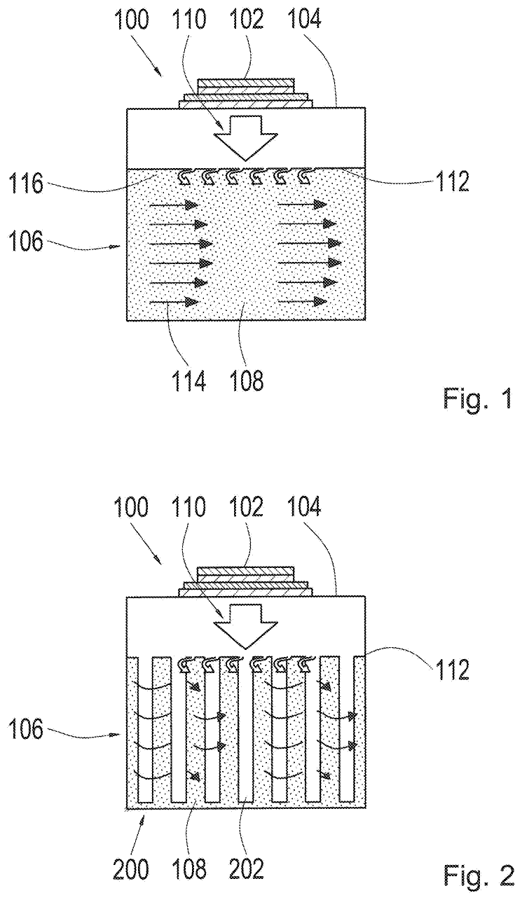

FIG. 1 shows an illustration of a conventional electronics module 100. The electronics module 100 has a power semiconductor 102 and a base plate 104. A cooling channel 106 for a coolant 108 is formed on a side of the base plate 104 lying opposite the power semiconductor 102. The base plate 104 forms one side of the cooling channel 106. The coolant 108 flows through the cooling channel 106.

Power losses in the form of heat 110 that is to be discharged occur at the power semiconductor 102. The base plate 104 is made of a thermally conductive material, e.g. copper. The power conductor 102 is soldered to the base plate 104, and thus connected thereto in a thermally conductive manner. The heat 110 passes through the base plate 104 and is transferred to the coolant 108 at a contact surface 112 between the base plate 104 and the coolant 108.

The coolant 108 flows in a laminar flow 114 through the cooling channel 106. The flow rate of the coolant 108 is strongest at the middle of the cooling channel 106, and decreases steadily toward the edges of the cooling channel 106. A boundary layer 16 with a low flow rate is formed in the region of the contact surface 112 due to the laminar flow 114. Furthermore, the coolant 108 is only slightly turbulent transverse to the direction of flow due to the laminar flow. In both cases, the coolant substantially absorbs heat 110 only in the region of the boundary layer 116.

Devices 100 are necessary for cooling or reducing the heat in heat generating components 102, which transfer heat 110 into a medium 108, remove it, and then discharge it into the environment.

Various types of heat exchangers 104 can be used as the device 100 for transferring heat 110 into a coolant 108. In the field of cooling power semiconductors 102, liquid cooled cooling concepts can be pursued, in which the heat 110 is conducted through a thermally conductive material 104, e.g. copper, to the heat transfer surface 112. A relatively cold coolant 108 flows over this transfer surface 112, resulting in a heat exchange. Water combined with a suitable anti-freeze, e.g. glycol, is usually used as the coolant 108.

Open or multi-part cooling channels 106 can be used to conduct the water/glycol mixture 108, in order to be able to replace the power semiconductor 102, or module in which the power semiconductor is located, and to provide the heat sink 104 with good heat transfer properties.

The power losses in the power module 102, or the IGBTs, heats up the IGBT 102, which should discharge the heat 110 as quickly and efficiently as possible. For this, it is attached to a cooling plate by solder and ceramic layers. The cooling plate 104 is usually made of a thermally conductive material, e.g. copper or aluminum, and is in direct contact with the coolant 108. The flow direction is indicated by arrows.

A purely laminar flow 114 with a flat boundary surface 112 without structures is illustrated in FIG. 1. With a flat base plate 104 without any turbulators the coolant 108 exhibits a laminar flow 114 at the boundary surface 112 between the water 108 and the copper plate 104. As soon as the coolant 108 begins to reach the temperature of the copper plate 104, it can no longer absorb any more heat. Coolant 108 that is deeper, i.e. lower along the z-axis, may however exhibit a lower temperature.

FIG. 2 shows an illustration of an electronics module 100 with a pin-fin structure 200. The electronics module 100 substantially corresponds to the electronics module in FIG. 1. In addition, there is a pin-fin structure 200 located on the base plate 104 in the region of the cooling channel 106. The pin-fin structure 200 has projections 202 made of a thermally conductive material, which extend into the cooling channel 106. The pin-fin structure 200 can also have its own base plate, which is connected in a thermally conductive manner to the base plate 104.

The coolant 108 flows over the pin-fin structure 200. The pin-fin structure 200 increases the surface area of the contact surface 112. The heat 110 is transported toward the middle of the flow at the projections 202 in the pin-fin structure 200, such that the heat 110 is absorbed by a larger portion of the coolant 108, and thus removed. The temperature of the projections 202 decreases as the distance to the base plate 104 increases, such that as the distance to the base plate 104 increases, the amount of heat 110 discharged into the coolant 108 decreases steadily, due to the decreasing temperatures between the projections 202 and the coolant 108.

The flow resistance in the cooling channel 106 is increased by the pin-fin structure 200. Starting at a certain flow rate, the flow in the region of the pin-fin structure 200 therefore becomes turbulent. As a result of the turbulent flow, the heat transfer between the contact surface 112 and the coolant 108 is improved. The pin-fin structure 200 obstructs the turbulence of the coolant 108 in a direction transverse to that of the flow.

The heat sinks 104 can have stationary structures 202, which extend into the coolant 108, thus sufficiently increasing the boundary surface 112, while also making the flow turbulent. These structures 202 can be so-called pin-fin structures 200, in which pins 202 made of copper extend into the coolant 108. This structure 200 is rigid, and requires that the cooling channel 106 and heat sink 104 be formed separately, because it would otherwise be impossible to produce this structure 200. The cooling channel 106 and the heat sink 104 are closed and sealed by means of joining technologies. This is obtained with either a rubber seal or through welding, e.g. friction stir welding.

A laminar flow with a pin-fin structure 200 in the form of a structure 202 that extends into the coolant 108 is shown in FIG. 2. Turbulence is generated in the coolant 108 through the use of stationary elements 202, such as the copper pins 202 projecting from the copper plate 104. The heat 110 can penetrate the coolant 108 further through the pins 202, and the stationary pins 202 also cause a turbulence in the flow along the y-axis. The elements 202 projecting into the coolant 108 can also have a variety of different geometric shapes, e.g. planes, webs, or blade-profiles.

In order to ensure a turbulent flow, stationary flow effecting elements 202 can be placed in the cooling channel 106, which cause a partial turbulence.

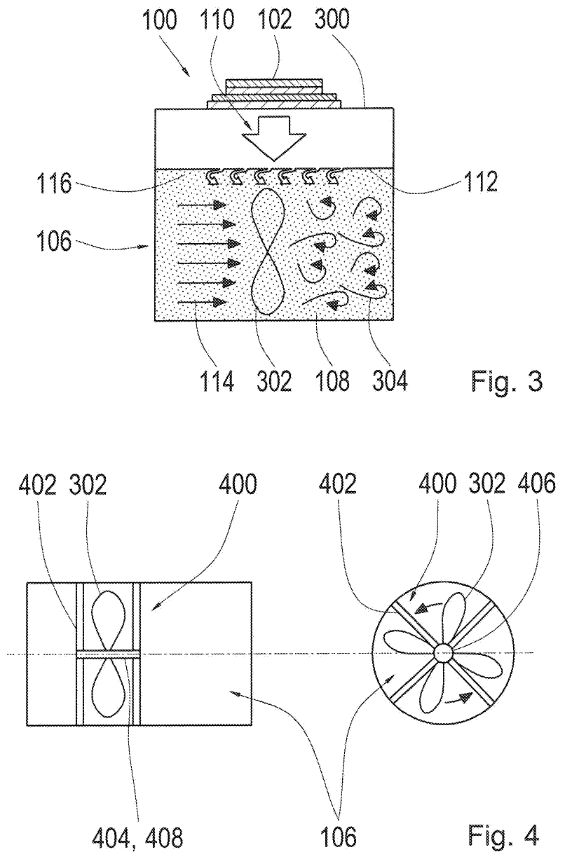

FIG. 3 shows an illustration of an electronics module 100 according to an exemplary embodiment of the present invention. The electronics module 100 corresponds substantially to the electronics module in FIG. 1. In contrast thereto, the power semiconductor 102 is located herein on a laser sintered heat sink 300, and connected thereto in a thermally conductive manner. Furthermore, the cooling channel 106 is formed as a recess in the integral laser sintered heat sink 300. A turbulence element 302 is located in the cooling channel 106 that is produced in the same sintering process as the heat sink 300. The laminar flow 114 strikes the turbulence element 302, and causes it to move. The movement converts the laminar flow 114 to a turbulent flow 304. The boundary layer 116 at the contact surface 112 is reduced to a minimum by the turbulent flow 304, and heat transfer between the contact surface 112 and the coolant 108 is improved. As a result of the unobstructed turbulence of the coolant 108 transverse to the direction of flow, colder coolant 108 is continuously conducted from the middle of the flow to the contact surface 112, while heated coolant 108 is conducted away from the contact surface 112. The substantially unobstructed cooling channel 106 has a low flow resistance.

In other words, an integrated turbulator 302 that ensures a turbulent flow 304 for an improved heat transfer is illustrated in FIG. 3.

With the approach presented herein, at least one integrated moving turbulator 302 is used for cooling power semiconductors 102 in an integrated device 300. The moving turbulator 302 is integrated directly in the heat sink 300 through the use of additive manufacturing technologies, and causes a turbulence 304 through movement caused by flow technologies, such that the boundary surfaces 112 are always subjected to a turbulent flow. Accordingly, a function that could not be produced conventionally can be integrated therein through the additive manufacturing.

The challenge presented in cooling is to conduct heat 110 toward the boundary surfaces 112, which are in contact with two media, i.e. metal and coolant 108, thus transferring the heat 110 into the coolant 108, i.e. the water/glycol mixture 108. In order to optimize the heat discharge to the liquid coolant 108, a turbulent flow 304 over the cooling surfaces 112 is preferred over a laminar flow 114. Ideally, coolant 108 should also be exchanged vertically, in order to continuously supply cold coolant 108 to the boundary surfaces 112.

A turbulent flow 304 with an integrated, exemplary moving propeller 302 serving as a turbulator 302 is illustrated in FIG. 3. By introducing a moving turbulator element 302 therein, turbulence is caused in the cooling channel 106, which continuously transports cold coolant 108 to the boundary surfaces 112. The turbulence takes place along the z-axis.

FIG. 4 shows an illustration of a propeller-shaped turbulence element 302 according to an exemplary embodiment of the present invention. The turbulence element 302 is shown from two perspectives. The turbulence element 302 is located in the cooling channel 106, as in FIG. 3. In addition, the turbulence element 302 has a retaining structure 400. The retaining structure 400 is integrally connected to the heat sink, and is laser sintered in the same sintering process as the turbulence element 302 and the heat sink. The turbulence element 302 is in the shape of a propeller herein. The turbulence element 302 has four propeller blades, extending radially in relation to a propeller hub. The propeller blades are set at an angle to the direction of flow. The retaining structure 400 has struts 402 and a rotation axle 404. The struts 402 are located in two planes on both sides of the turbulence element 302, transverse to the cooling channel 106, and form crosses in each case. The rotation axle 404 passes between the intersections of the struts 402. The rotation axle 404 is substantially axial to the cooling channel 106 on a central axis of the cooling channel 106. The turbulence element 302 can rotate about the rotation axle 404. For this, the propeller hub has a through hole, in which the rotation axle 404 is located.

In one exemplary embodiment, the retaining structure 400 comprises the struts 402 and two bearing points 406 for a propeller shaft 408 of the turbulence element 302. The bearing points 406 are located in the two planes on both sides of the turbulence element 302, at the intersections of the struts 402. The bearing points 406 can be in the form of through holes or blind holes, for example, for shaft ends of the propeller shaft 408.

A propeller 302 is shown by way of example in FIG. 4, which is placed in the cooling channel 106 on retaining rods 402. The cooling channel 106 can be produced integrally through the use of the additive manufacturing process or 3D printing of metal. There is no need for complicated two- or multi-part housing components that have to be screwed together. As a result of this process, it is also possible to integrate an additional function therein.

The cooling channel 106 can be an integral component, wherein the moving part 302 is already integrated therein during production thereof. The at least one moving part 302 is placed directly in a cooling circuit, such that a turbulence flows over the heat discharging surface. The moving part 302 can be made of a metal substance and of plastic.

In one exemplary embodiment, at least one propeller-like component 302 is placed in the cooling channel 106. The moving part 302 is attached to retaining struts. The internal propeller 302 is then set in motion by the flow, and causes a turbulent flow.

By cascading numerous propellers 302 in diverse embodiments, e.g. perforated or irregular, numerous flow variations can be formed.

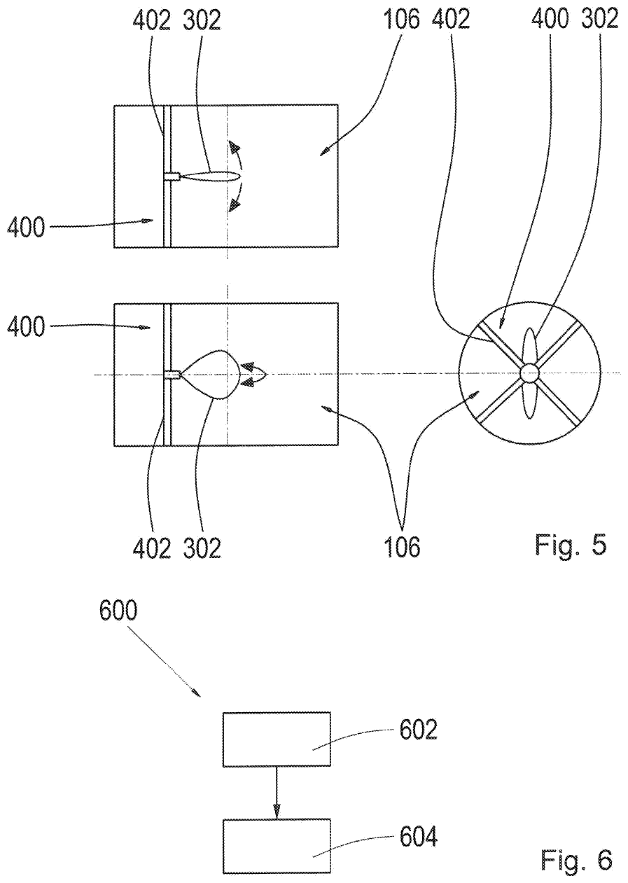

FIG. 5 shows an illustration of a paddle-shaped turbulence element 302 according to an exemplary embodiment of the present invention. The turbulence element 302 is shown from three perspectives. The turbulence element 302 is located centrally in the cooling channel 106, as in FIG. 4. The retaining structure 400 has struts 402, as in FIG. 4. In contrast to the illustration in FIG. 4, the struts are located herein in a plane that is upstream of the turbulence element 302 in the direction of flow. The struts 402 are located transverse to the cooling channel 106 in the form of a cross, as in FIG. 4. The turbulence element 302 is connected to the struts 402 at an intersection of the struts 402 such that it can oscillate.

The turbulence element 302 in this case is a flat oscillating element in the shape of a beaver tail. The turbulence element 302 is connected to the retaining structure 400 at its upstream end. When the coolant flows around the turbulence element 302, opposing turbulences are formed at the opposing flat sides of the turbulence element 302, which cause the turbulence element 302 to oscillate back and forth, or to flutter, which in turn increases the turbulence. The turbulences are released from the turbulence element 302 at the trailing edge, and cause a turbulence in the coolant transverse to the direction of flow.

In one exemplary embodiment, at least one moving element 302 is pressed into the cooling channel 106, which moves in the liquid flow in the manner of an artificial fishing lure 302. This is likewise retained in the cooling channel 106 by retaining webs 402, and causes turbulence in the coolant through the flow in the channel 106.

Further turbulences can be triggered by placing at least two successive turbulence elements 302 in the cooling channel.

FIG. 6 shows a flow chart for a method 600 for the production of an electronics module according to an exemplary embodiment of the present invention. The method has a providing step 602 and a connecting step 604. In the provision step 602, a power semiconductor and an integrated laser sintered heat sink that has at least one cooling channel are provided. A turbulence element that is laser sintered with the heat sink in a process is located in the cooling channel. In the connecting step 604, the power semiconductor is connected in a thermally conductive manner to the heat sink.

The exemplary embodiments described herein and shown in the figures are selected merely by way of example. Different exemplary embodiments can be combined with one another, in and of themselves or with respect to individual features. Moreover, one exemplary embodiment can be supplemented with features of another exemplary embodiment.

Furthermore, method steps according to the invention can be repeated, or executed in a sequence other than that described herein.

If an exemplary embodiment comprises an “and/or” conjunction between a first feature and a second feature, this can be read to mean that the exemplary embodiment according to one embodiment contains both the first and second feature, and according to another embodiment, contains either just the first feature or just the second feature.

### REFERENCE SYMBOLS

10 blank

12 strips

13 cross-strip

20 plastic material

100 steering element

110 reinforcement structure

120 stiffening structure

131 bearing receiver

132 bearing receiver

133 bearing receiver

134 bearing receiver

141 ball pin

142 rubber bearing

143 rubber bearing

150 load sensor

160 elastomer layer

200 compression mold

210 cavity

P compression process

1. An electronics module comprising
at least one power semiconductor connected to an integral laser sintered heat sink in a thermally conductive manner; and
a turbulence element that is movable in a laser sintered cooling channel of the heat sink, wherein the turbulence element is laser sintered with the heat sink.

2. The electronics module according to claim 1, wherein the heat sink is laser sintered from a metal material, and wherein the power semiconductor is soldered to the heat sink.

3. The electronics module according to claim 1, wherein the power semiconductor is an IGBT.

4. The electronics module according to claim 1, wherein a laser sintered shaft of the turbulence element is rotatably supported in the cooling channel.

5. The electronics module according to claim 1, wherein the turbulence element is rotatably supported on a laser sintered axle located in the cooling channel.

6. The electronics module according to claim 1, wherein the turbulence element is perforated.

7. The electronics module according to claim 1, wherein the turbulence element has an irregular shape.

8. The electronics module according to claim 1, wherein the turbulence element includes a propeller.

9. The electronics module according to claim 1, wherein the turbulence element includes a paddle.

10. The electronics module according to claim 1, wherein the turbulence element is laser sintered from a plastic material.

11. The electronics module according to claim 1, which has at least one further turbulence element that can move in the cooling channel, which is laser sintered with the heat sink in a process.

12. A method for the production of an electronics module, wherein the method comprises the following steps:
forming a power semiconductor and an integral laser sintered heat sink that has at least one cooling channel, wherein a turbulence element is laser sintered with the heat sink in an integral process; and
connecting the power semiconductor to the heat sink.

13. The method of claim 12, wherein the turbulence element is movable within the at least one cooling channel of the heat sink.

14. The method of claim 13, further comprising forming the at least one cooling channel via laser sintering.

15. The method of claim 12, wherein the heat sink is laser sintered from a metal material, and wherein the power semiconductor is soldered to the heat sink.

16. The method of claim 12, wherein the power semiconductor is an IGBT.

17. The method of claim 12, wherein a laser sintered shaft of the turbulence element is rotatably supported in the at least one cooling channel.

18. The method of claim 12, wherein the turbulence element is rotatably supported on a laser sintered axle located in the at least one cooling channel.

19. The method of claim 12, wherein the turbulence element is perforated.

20. The method of claim 12, wherein the turbulence element include at least one of a propeller and a paddle.
